(19) United States
(12) Patent Application Publication
(10) Pub. No.: US 2016/0086912 A1
(43) Pub. Date: Mar. 24, 2016

(54) METHODS FOR SEMICONDUCTOR PACKAGE

(71) Applicant: SAMSUNG ELECTRONICS CO., LTD., Suwon-si (KR)

(72) Inventor: Teakhoon Lee, Hwaseong-si (KR)

(21) Appl. No.: 14/721,624

(22) Filed: May 26, 2015

(30) Foreign Application Priority Data
Sep. 19, 2014 (KR) 10-2014-0125097

(51) Int. Cl. H01L 23/00; H01L 25/00; H01L 21/48

(52) U.S. Cl. CPC H01L 24/83; H01L 21/4889; H01L 25/50; H01L 2224/83203; H01L 2224/8385

(57) ABSTRACT

A method for manufacturing a semiconductor package includes providing a first semiconductor chip having a first surface and a second surface opposing each other, the first semiconductor chip including through-electrodes extending between the first surface and the second surface, forming an adhesive layer on the first surface, providing the first semiconductor chip on a package substrate so that the adhesive layer contacts the package substrate, thermo-compressing the first semiconductor chip so that the adhesive layer protrudes from between the first semiconductor chip and the package substrate towards the outside of the first semiconductor chip to form a support part that covers sides of the first semiconductor chip, and providing a second semiconductor chip on the first semiconductor chip, the second semiconductor chip having a third surface and a fourth surface opposing each other, the second semiconductor chip including connection terminals formed on the third surface.

### CROSS-REFERENCE TO RELATED APPLICATION(S)

This application claims priority under 35 U.S.C. §119 to Korean Patent Application No. 10-2014-0125097, filed on Sep. 19, 2014, the contents of which are herein incorporated by reference in their entirety.

### TECHNICAL FIELD

Exemplary embodiments of the present disclosure relate to a method for manufacturing a semiconductor package.

### DISCUSSION OF THE RELATED ART

Electronic products using semiconductor devices may be required to have a high capacity, to be thin and to be small. To meet such requirements, various package technologies have been developed in a semiconductor industry. A package technology enables high-density chip lamination through vertical stacking of various semiconductor chips. According to this technology, semiconductor chips having various functions may be integrated in a smaller area than that of a typical package including a single semiconductor chip. According to this technology, a package may easily dissipate heat generated from a semiconductor chip and may improve the stability of the stacked semiconductor chips.

### SUMMARY

The present disclosure provides a method for manufacturing a semiconductor package in which a relatively large semiconductor chip staked on a relatively small semiconductor chip may be securely supported.

An Exemplary embodiment of the inventive concept provides a method for manufacturing a semiconductor package, including providing a first semiconductor chip having a first surface and a second surface opposing each other, the first semiconductor chip including through-electrodes extending between the first surface and the second surface, forming an adhesive layer on the first surface of the first semiconductor chip, providing the first semiconductor chip on a package substrate so that the adhesive layer contacts the package substrate, thermo-compressing the first semiconductor chip so that the adhesive layer protrudes from between the first semiconductor chip and the package substrate towards the outside of the first semiconductor chip to form a support part that covers sides of the first semiconductor chip, providing a second semiconductor chip on the first semiconductor chip, the second semiconductor chip having a third surface and a fourth surface opposing each other, the second semiconductor chip including connection terminals formed on the third surface, providing a nonconductive layer between the third surface of the second semiconductor chip and the second surface of the first semiconductor chip, thermo-compressing the nonconductive layer so that the connection terminals of the second semiconductor chip are electrically connected to the through-electrodes of the first semiconductor chip, and forming a molding layer covering at least sides of the second semiconductor chip. An upper surface of the support part is substantially flush with the second surface of the first semiconductor chip.

In some exemplary embodiments of the inventive concept, the second semiconductor chip may have a larger width than that of the first semiconductor chip and protrudes outwardly beyond sides of the first semiconductor chip.

In some exemplary embodiments of the inventive concept, the second semiconductor chip may have the same width as the first semiconductor chip.

In some exemplary embodiments of the inventive concept, the thermo-compressing the first semiconductor chip may include thermo-compressing the first semiconductor chip using a bonding tool that has a width equal to or larger than a width of the second semiconductor chip.

In some exemplary embodiments of the inventive concept, the support part may be formed so that a sum of a width of the first semiconductor chip and a width of the support part is substantially equal to or larger than a width of the second semiconductor chip.

In some exemplary embodiments of the inventive concept, the nonconductive layer may include a nonconductive paste or a nonconductive film.

In some exemplary embodiments of the inventive concept, the nonconductive layer may have a thickness larger than a height of the connection terminals.

In some exemplary embodiments of the inventive concept, the adhesive layer may include an epoxy-based, silicon-based, phenol-type or acid anhydride hardening agent, an amine-type hardening agent or an acrylic-polymer-containing hardening material.

In some exemplary embodiments of the inventive concept, the forming the molding layer may include forming the molding layer that covers sides of the support part and the second semiconductor chip and exposes the fourth surface of the second semiconductor chip.

In some exemplary embodiments of the inventive concept, the method may further include forming a heat transfer layer on the fourth surface of the second semiconductor chip, and forming a heat dissipating layer on the heat transfer layer.

In an exemplary embodiment of the inventive concept, a method for manufacturing a semiconductor package includes providing a first semiconductor chip having a first surface and a second surface opposing each other, the first semiconductor chip including first through-electrodes extending between the first surface and the second surface, forming an adhesive layer on the first surface of the first semiconductor chip, providing the first semiconductor chip on a package substrate so that the adhesive layer contacts the package substrate, thermo-compressing the first semiconductor chip using a bonding tool wider than the first semiconductor chip so that the adhesive layer protrudes from between the first semiconductor chip and the package substrate towards the outside of the first semiconductor chip to form a support part that covers sides of the first semiconductor chip, providing a second semiconductor chip on the first semiconductor chip, the second semiconductor chip having a third surface and a fourth surface opposing each other, the second semiconductor chip including connection terminals formed on the third surface, providing a nonconductive layer between the third surface of the second semiconductor chip and the second surface of the first semiconductor chip, and thermo-compressing the nonconductive layer so that the connection terminals of the second semiconductor chip are electrically connected to the first through-electrodes of the first semiconductor chip. The support part contacts the nonconductive layer and an upper surface of the support part is substantially flush with the second surface of the first semiconductor chip.

In some exemplary embodiments of the inventive concept, the second semiconductor chip may have a larger width than that of the first semiconductor chip and protrudes outwardly beyond sides of the first semiconductor chip.

In some exemplary embodiments of the inventive concept, the second semiconductor chip may have the same width as the first semiconductor chip.

In some exemplary embodiments of the inventive concept, the first through-electrodes may be arranged in a center region of the first semiconductor chip.

In some exemplary embodiments of the inventive concept, the second semiconductor chip may include second through-electrodes connected to the connection terminals, the second through-electrodes extending between the third surface and the fourth surface. The second through-electrodes of the second semiconductor chip may be electrically connected to the first through-electrodes of the first semiconductor chip.

In some exemplary embodiments of the inventive concept, the adhesive layer may include an epoxy-based, silicon-based, phenol-type or acid anhydride hardening agent, an amine-type hardening agent or an acrylic-polymer-containing hardening material.

In an exemplary embodiment of the inventive concept, a method for manufacturing a semiconductor package includes providing a first semiconductor chip having a first surface and a second surface opposing each other, the first semiconductor chip comprising first through-electrodes extending between the first surface and the second surface, forming an adhesive layer on the first surface of the first semiconductor chip, providing the first semiconductor chip on a package substrate so that the adhesive layer contacts the package substrate, thermo-compressing the first semiconductor chip using a bonding tool wider than the first semiconductor chip so that the adhesive layer protrudes from between the first semiconductor chip and the package substrate towards the outside of the first semiconductor chip to form a support part that covers sides of the first semiconductor chip, providing a second semiconductor chip on the first semiconductor chip, the second semiconductor chip having a third surface and a fourth surface opposing each other, the second semiconductor chip comprising second through-electrodes that extend between the third surface and the fourth surface and connection terminals formed on the third surface, providing a nonconductive layer between the third surface of the second semiconductor chip and the second surface of the first semiconductor chip, and thermo-compressing the nonconductive layer so that the connection terminals of the second semiconductor chip are electrically connected to the first through-electrodes of the first semiconductor chip. The support part may contact the nonconductive layer and an upper surface of the support part is substantially flush with the second surface of the first semiconductor chip.

In some exemplary embodiments of the inventive concept, the second semiconductor chip has a larger width than that of the first semiconductor chip and protrudes outwardly beyond sides of the first semiconductor chip.

In some exemplary embodiments of the inventive concept, the second semiconductor chip has the same width as the first semiconductor chip.

In some exemplary embodiments of the inventive concept, the first through-electrodes are arranged in a center region of the first semiconductor chip.

### BRIEF DESCRIPTION OF THE DRAWINGS

The inventive concept will become more apparent and more readily appreciated by describing in detail exemplary embodiments of the inventive concept in which:

FIGS. 1A to 1F are cross-sectional views illustrating a method for manufacturing a semiconductor package according to an exemplary embodiment of the inventive concept;

FIG. 2A is a plan view illustrating the first semiconductor chip of FIG. 1B;

FIG. 2B is a plan view illustrating the second semiconductor chip of FIG. 1D;

FIG. 2C is a plan view illustrating a part of FIG. 1F;

FIG. 3 is a cross-sectional view illustrating a semiconductor package according to an exemplary embodiment of the inventive concept;

FIG. 4 is a cross-sectional view illustrating a semiconductor package according to an exemplary embodiment of the inventive concept;

FIG. 5 is a cross-sectional view illustrating a semiconductor package according to an exemplary embodiment of the inventive concept;

FIG. 6 is a cross-sectional view illustrating a semiconductor package according to an exemplary embodiment of the inventive concept;

FIG. 7 is a block diagram illustrating a memory system including a semiconductor package according to one or more exemplary embodiments of the inventive concept; and

FIG. 8 is a block diagram illustrating an electronic system including a semiconductor package according to one or more exemplary embodiments of the inventive concept.

### DETAILED DESCRIPTION OF THE EMBODIMENTS

Exemplary embodiments of the inventive concept will be described below in more detail with reference to the accompanying drawings. The inventive concept may, however, be embodied in different forms and should not be construed as being limited to the exemplary embodiments described herein. The exemplary embodiments of the inventive concept are provided to convey the inventive concept to those skilled in the art.

The exemplary embodiments of the inventive concept will be described with reference to example cross-sectional views and/or plan views. In the drawings, the dimensions of layers and regions may be exaggerated for clarity of illustration. However, the shapes illustrated in the drawings may be changed due to a manufacturing technology and/or error tolerance. The exemplary embodiments of the inventive concept may include shape changes resulting from the manufacturing technology, and may not be limited to the specific shapes illustrated in the drawings. For example, an etching region illustrated as being angular may be rounded or curved. Therefore, the regions illustrated in the drawings are merely schematic and may not limit the scope of the inventive concept.

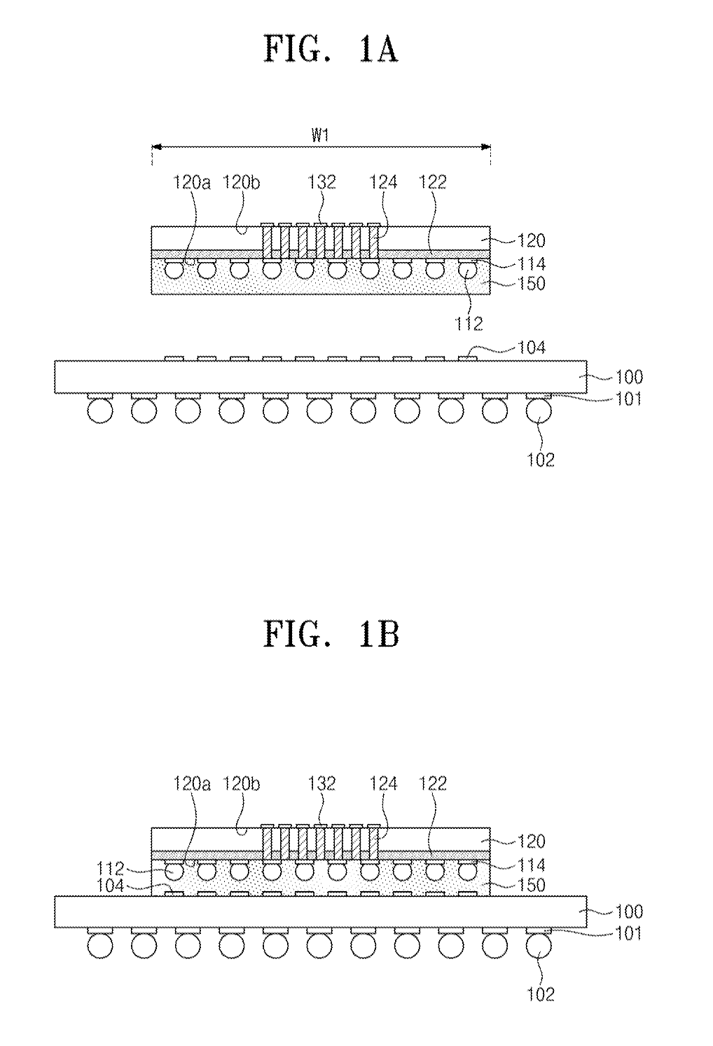

FIGS. 1A to 1F are cross-sectional views illustrating a method for manufacturing a semiconductor package according to an exemplary embodiment of the inventive concept.

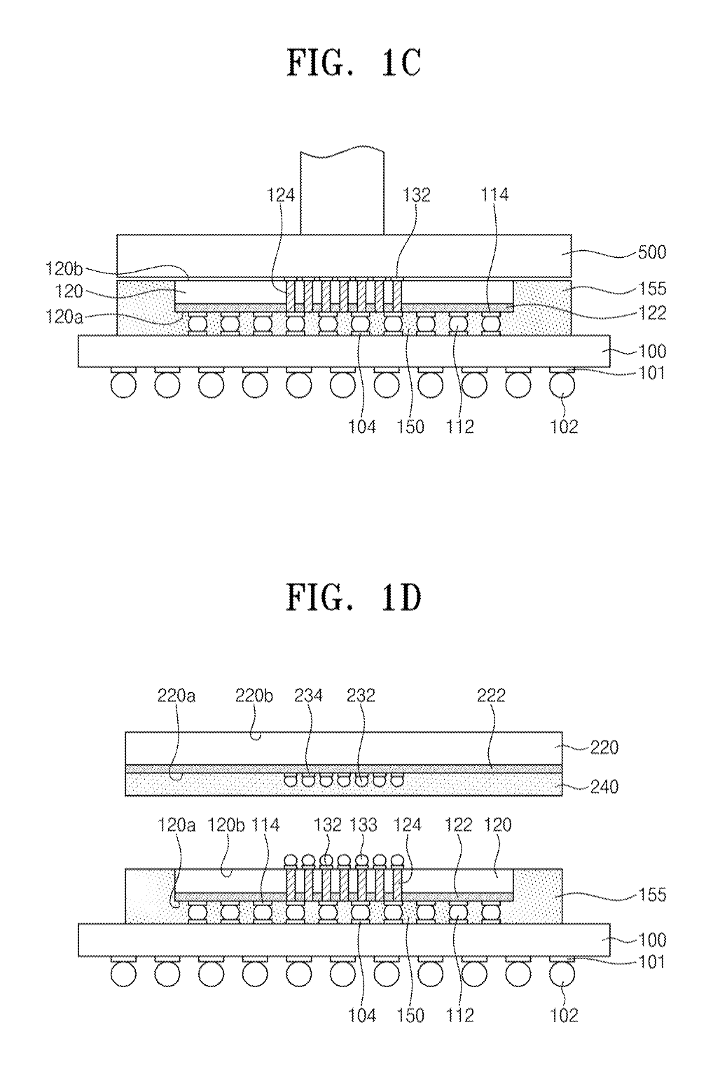

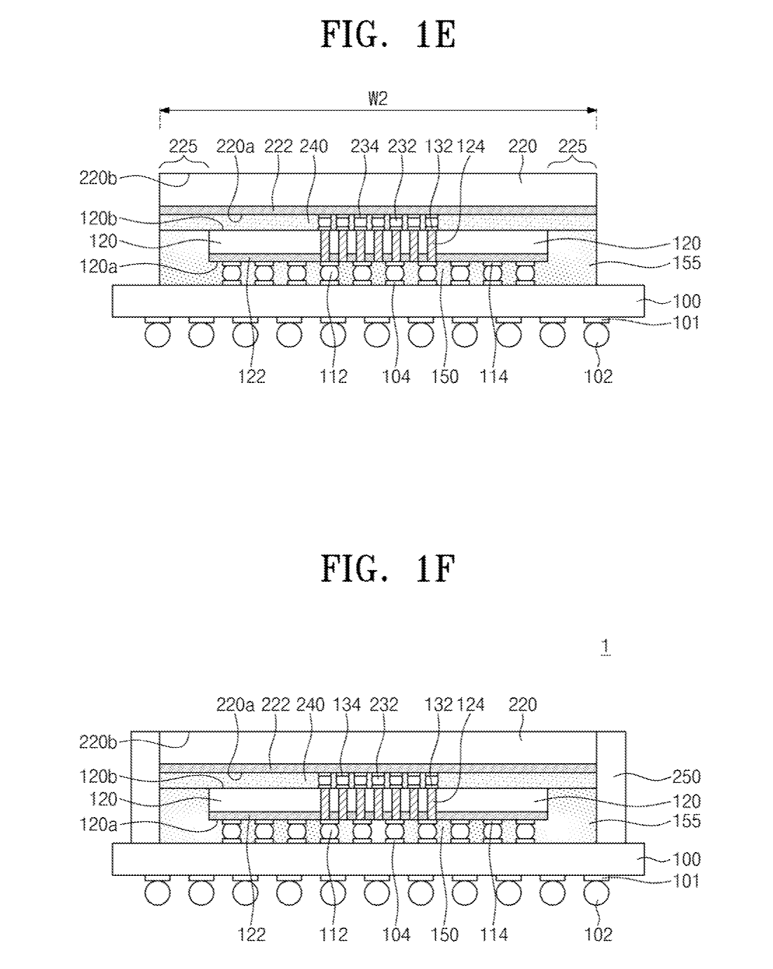

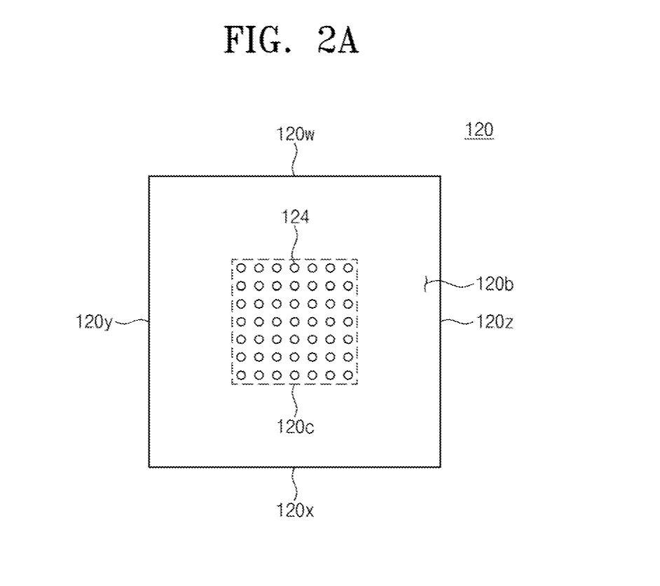

Referring to FIGS. 1A and 1B, a first semiconductor chip 120 may be mounted on a package substrate 100. The package substrate 100 may be, for example, a printed circuit board (PCB). External terminals 102 such as solder balls may be bonded to a lower surface of the package substrate 100. First substrate pads 101 may be provided between the package substrate 100 and the external terminals 102. Second substrate pads 104 may be provided to an upper surface of the package substrate 100. A first semiconductor chip 120 may include a first surface 120a and a second surface 120b opposing each other. A first circuit layer 122 may be disposed adjacent to the first surface 120a. The first surface 120a may be an active surface, and the second surface 120b may be an inactive surface. The first semiconductor chip 120 may include through-electrodes 124 that pass through the first semiconductor chip 120 to be electrically connected to the first circuit layer 122. The through-electrodes 124 may extend vertically between the first surface 120a and the second surface 120b. As illustrated in FIG. 2A, the through-electrodes 124 may be arranged in a center region 120c of the first semiconductor chip 120. The first semiconductor chip 120 may be, for example, a non-memory chip such as a controller, a microprocessor or an application processor.

The first semiconductor chip 120 may have a first width W1. As illustrated in FIG. 2A, at least one pair of opposing sides, for example, 120w and 120x, among four sides 120w, 120x, 120y and 120z of the first semiconductor chip 120 may have the same length as the first width W1.

An adhesive layer 150 may be formed on the first surface 120a of the first semiconductor chip 120. The adhesive layer 150 may include an epoxy-based, silicon-based, phenol-type or acid anhydride hardening agent, an amine-type hardening agent or an acrylic-polymer-containing hardening material. Connectors 112 such as solder balls or solder bumps may be provided between the first surface 120a of the first semiconductor chip 120 and the upper surface of the package substrate 100. The connectors 112 may be, for example, solder balls or solder bumps. First connection pads 114 may be provided between the first semiconductor chip 120 and the connectors 112. The connectors 112 may be coupled to the second substrate pads 104 so that the first semiconductor chip 120 may be electrically connected to the package substrate 100. Second connection pads 132 electrically connected to the through-electrodes 124 may be provided on the second surface 120b of the first semiconductor chip 120.

The first semiconductor chip 120 may be provided on the upper surface of the package substrate 100, and the adhesive layer 150 is in contact with the package substrate 100.

Referring to FIG. 1C, the first semiconductor chip 120 provided on the package substrate 100 may be thermo-compressed using a bonding tool 500. Accordingly, the adhesive layer 150 provided to the first surface 120a of the first semiconductor chip 120 is pressed so as to protrude from between the first semiconductor chip 120 and the package substrate 100 towards the outside of the first semiconductor chip 120, to form a support part 155. The support part 155 may cover the sides of the first semiconductor chip 120. The bonding tool 500 may have a larger width than that of the first semiconductor chip 120. For example, the bonding tool 500 may have a width equal to or larger than that of a second semiconductor chip 220 as shown in FIG. 1D. Due to the bonding tool 500, the support part 155 may have an upper surface that is substantially flush with the upper surface of the first semiconductor chip 120. Referring to FIG. 1E, since the upper surface of the support part 155 is substantially flush with the upper surface of the first semiconductor chip 120, the second semiconductor chip 220 may be prevented from being inclined. Here, the support part 155 may be formed such that a sum of the width of the first semiconductor chip 120 and the width of the support part 155 is substantially equal to the width of the second semiconductor chip 220.

Referring to FIGS. 1D and 1E, the second semiconductor chip 220 may be provided on the first semiconductor chip 120. The second semiconductor chip 220 may include a third surface 220a and a fourth surface 220b opposing each other. A second circuit layer 222 of the second semiconductor chip 220 may be formed adjacent to the third surface 220a. The third surface 220a of the second semiconductor chip 220 may be an active surface, and the fourth surface 220b may be an inactive surface. The second semiconductor chip 220 may have a larger width than that of the first semiconductor chip 120 so as to protrude outwardly beyond sides of the first semiconductor chip 120. The second semiconductor chip 220 may be, for example, a memory chip. The second semiconductor chip 220 may include first connection terminals 232 provided on the third surface 220a and electrically connected to the second circuit layer 222. The first connection terminals 232 may be, for example, solder balls or solder bumps. Third connection pads 234 may be provided between the first connection terminals 232 and the second circuit layer 222. As illustrated in FIG. 2B, the first connection terminals 232 may be arranged in a center region 220c of the active surface 220a of the second semiconductor chip 220. The first connection terminals 232 may be vertically aligned with the through-electrodes 124.

The second semiconductor chip 220 may have a second width W2 larger than the first width W1 of the first semiconductor chip 120. As illustrated in FIG. 2B, at least one pair of opposing sides, for example, 220w and 220x, among four sides 220w, 220x, 220y and 220z of the second semiconductor chip 220 may have the same length as the second width W2.

The second semiconductor chip 220 may be stacked face down on the first semiconductor chip 120 so that the third surface 220a opposes the package substrate 100. The third surface 220a of the second semiconductor chip 220 may oppose the second surface 120b of the first semiconductor chip 120. For example, the active surface of the second semiconductor chip 220 may oppose the inactive surface of the first semiconductor chip 120. In one or more exemplary embodiments of the inventive concept, solder pads 133 such as solder bumps or solder balls may be bonded to the second connection pads 132.

A nonconductive layer 240 may be provided on the third surface 220a of the second semiconductor chip 220. The nonconductive layer 240 may include a nonconductive paste (NCP) or a nonconductive film (NCF). The nonconductive layer 240 may be an epoxy-based material not containing conductive particles. The nonconductive layer 240 may have a thickness larger than a height of the first connection terminals 232. The nonconductive layer 240 is thermo-compressed and is thus decreased in thickness. Since the thickness of the nonconductive layer 240 is larger than the height of the first connection terminals 232, the first connection terminals 232 may be protected.

The second semiconductor chip 220 may be electrically connected to the first semiconductor chip 120 by thermo-compressing the nonconductive layer 240. For example, the nonconductive layer 240 may be thermo-compressed by applying a higher pressure than a normal pressure (e.g., 0.1 MPa) thereto at a higher temperature than a room temperature (e.g., 25° C.). Accordingly, the first connection terminals 232 contact the second connection pads 132 since the nonconductive layer 240 is pressed. Therefore, the second semiconductor chip 220 may be electrically connected to the first semiconductor chip 120. Since the nonconductive layer 240 is pressed, the nonconductive layer 240 may become thin and may protrude towards the outside of the second semiconductor chip 220. The protruding nonconductive layer 240 may be cut or may be supported by the support part 155. The nonconductive layer 240 may contact the support part 155.

Since the nonconductive layer 240 that does not contain conductive particles is used, the connection terminals 232 may have a small pitch and may avoid a short circuit between adjacent connection terminals 232. Since the first connection terminals 232 directly contact the second connection pads 132, a contact resistance may be decreased. The nonconductive layer 240 may serve as an underfill for filling a space between the second semiconductor chip 220 and the first semiconductor chip 120. Therefore, the mechanical durability of the first connection terminals 232 may be improved.

Since the second width W2 of the second semiconductor chip 220 is larger than the first width W1 of the first semiconductor chip 120, the second semiconductor chip 220 may have an overhang 225 that protrudes outwardly beyond sides of the first semiconductor chip 120. For example, as illustrated in FIG. 2C, the overhang 225 may have the shape of an annulus extending along the perimeter of the first semiconductor chip 120. Also, the overhang 225 may be disposed on outer edges of opposing sides of the first semiconductor chip 120. According to an exemplary embodiment of the inventive concept, since the support part 155 may support the overhang 225, a semiconductor package 1 does not substantially have an overhang structure.

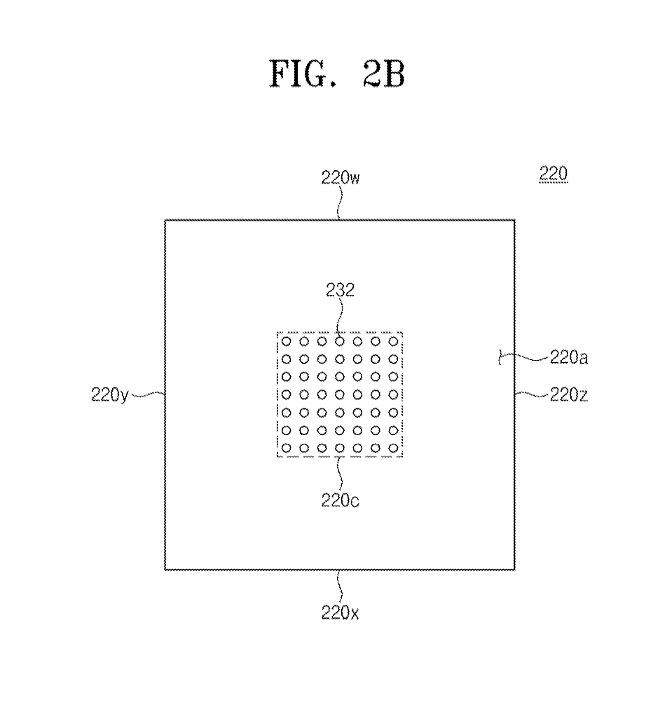

Referring to FIG. 1F, a molding layer 250 may be formed to cover the first and second semiconductor chips 120 and 220. The molding layer 250 may cover sides of the support part 155 and second semiconductor chips 120 and 220. The molding layer 250 may protect sides of the first and second semiconductor chips 120 and 220. The molding layer 250 may expose the fourth surface 220b of the second semiconductor chip 220. As illustrated in FIG. 3, the molding layer 250 that completely covers the second semiconductor chip 220 may be formed to manufacture a semiconductor package 2.

According to an exemplary embodiment of the inventive concept, even though the second semiconductor chip 220 has a larger size than that of the first semiconductor chip 120, the support part 155 may support the nonconductive layer 240 and the second semiconductor chip 220. Therefore, the second semiconductor chip 220 may be prevented from being inclined or broken.

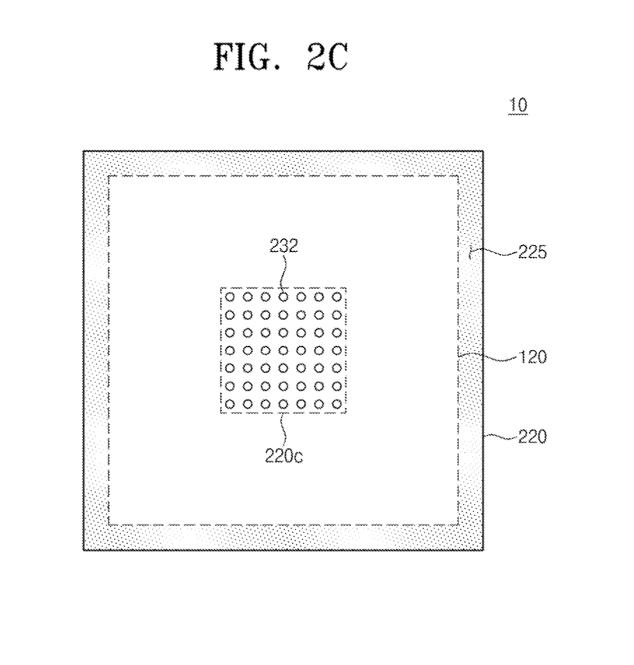

FIG. 4 is a cross-sectional view illustrating a semiconductor package 3 according to an exemplary embodiment of the inventive concept.

A heat transfer layer 300 and a heat dissipating layer 310 may be stacked on the fourth surface 220b of the second semiconductor chip 220 to manufacture the semiconductor package 3. The heat dissipating layer 310 includes a conductive material. For example, the heat dissipating layer 310 may include copper or aluminum. The heat transfer layer 300 may include thermal grease, a phase change material or a thermal conductive elastomer. Heat generated by the second semiconductor chip 220 may be transferred to the heat transfer layer 300 and the heat dissipating layer 310 through the fourth surface 220b exposed by the molding layer 250 to be easily dissipated to the outside. Therefore, the semiconductor package 3 may have a good heat dissipating characteristic.

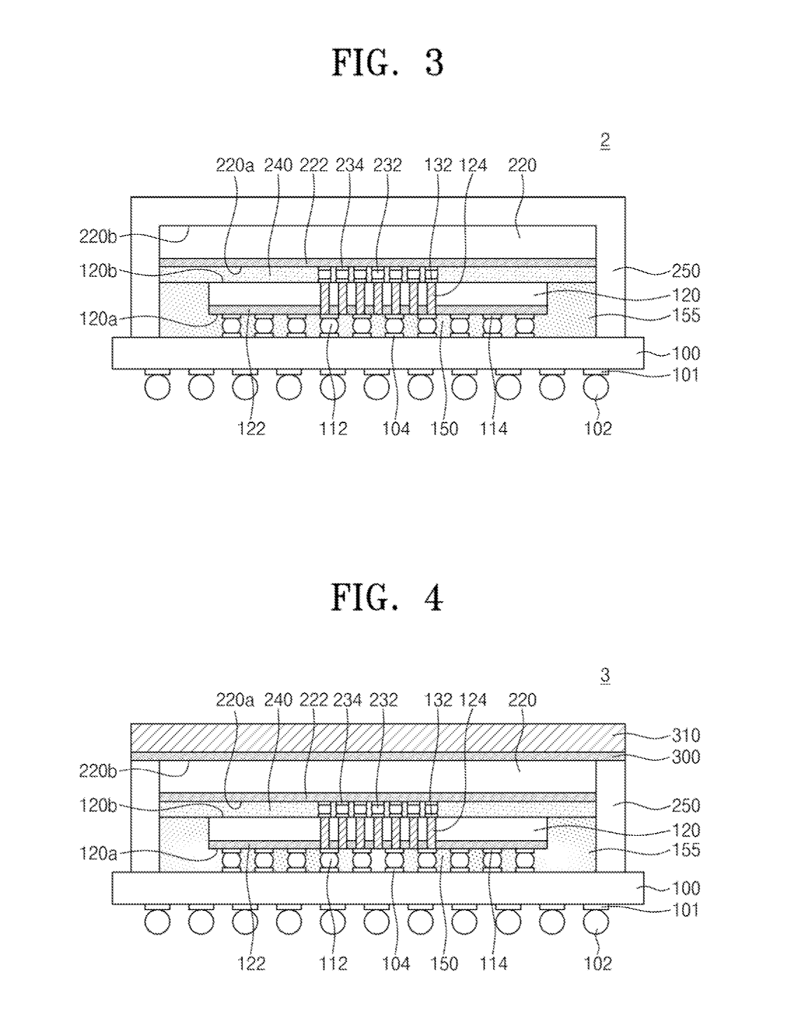

FIG. 5 is a cross-sectional view illustrating a semiconductor package 4 according to an exemplary embodiment of the inventive concept.

Referring to FIG. 5, the first semiconductor chip 120 may have the same width as the second semiconductor chip 220 in the semiconductor package 4. The adhesive layer 150 may be formed on the first surface 120a of the first semiconductor chip 120. The first semiconductor chip 120 may be thermo-compression bonded to the package substrate 100 using the bonding tool 500 of FIG. 1C. The bonding tool 500 may have a larger width than that of the first semiconductor chip 120. The adhesive layer 150 provided to the first surface 120a of the first semiconductor chip 120 is pressed so as to protrude from between the first semiconductor chip 120 and the package substrate 100 towards the outside of the first semiconductor chip 120 to form the support part 155. The support part 155 may cover sides of the first semiconductor chip 120. An entire width of the support part 155 may include a sum of a width of the support part 155 formed on one side (e.g., a right side) of the first semiconductor chip 120 and a width of the support part 155 formed on the opposing side (e.g., a left side) of the first semiconductor chip 120. A sum of the width of the first semiconductor chip 120 and the entire width of the support part 155 is equal to or larger than the width of the second semiconductor chip 220. The molding layer 250 may be provided on the support part 155. The molding layer 250 may cover sides of the nonconductive layer 240 and the second semiconductor chip 220. The molding layer 250 may expose the fourth surface 220b of the second semiconductor chip 220. In one or more exemplary embodiments of the inventive concept, the molding layer 250 may completely cover the second semiconductor chip 220.

In an exemplary embodiment of the inventive concept, an overhang structure is not formed because the first semiconductor chip 120 has the same size as the second semiconductor chip 220. However, in the case of thermo-compressing the second semiconductor chip 220, the nonconductive layer 240 may protrude towards the outside of the second semiconductor chip 220. The support part 155 may contact and support the protruding nonconductive layer 240 and may prevent the second semiconductor chip 220 from being inclined or broken.

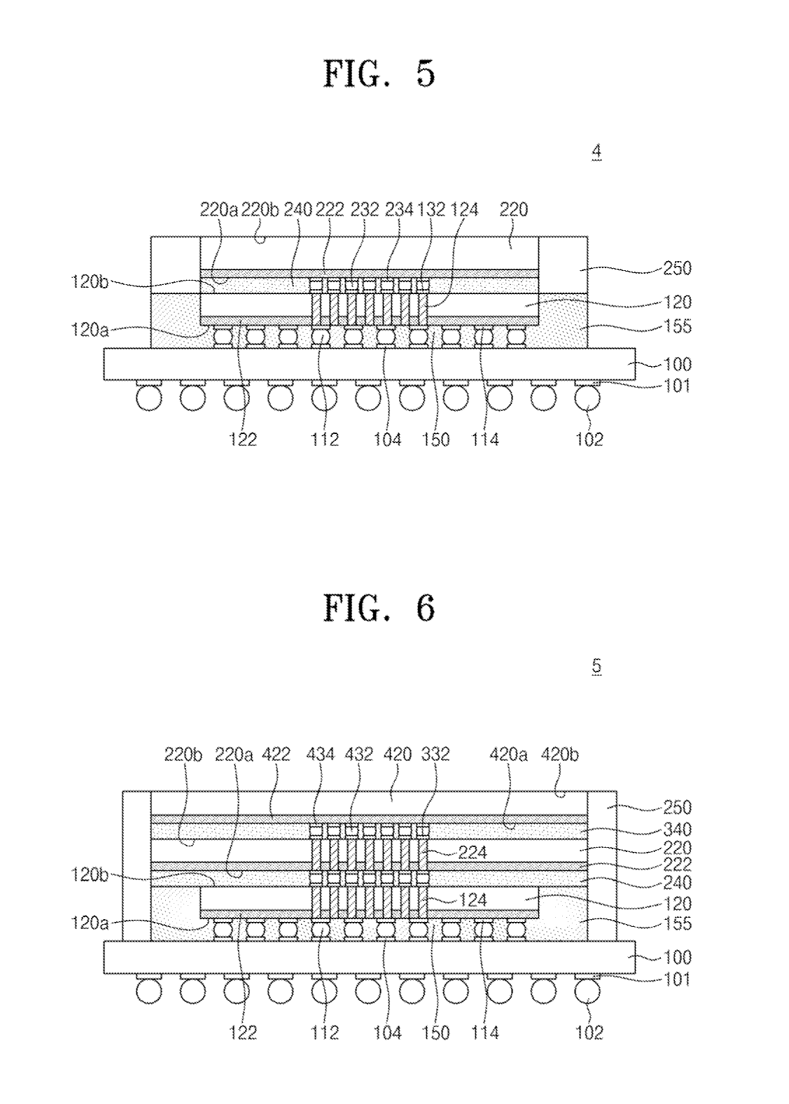

FIG. 6 is a cross-sectional view illustrating a semiconductor package 5 according to an exemplary embodiment of the inventive concept.

Referring to FIG. 6, the first semiconductor chip 120 may be mounted on the package substrate 100 to form the support part 155, and the second semiconductor chip 220 may be stacked on the first semiconductor chip 120, in the same manner as described above with reference to FIGS. 1A to 1D. A third semiconductor chip 420 may be stacked on the second semiconductor chip 220 to manufacture the semiconductor package 5. In an exemplary embodiment of the inventive concept, a second semiconductor chip 220 may include second through-electrodes 224 that pass through the second semiconductor chip 220. The second semiconductor chip 220 may have fourth connection pads 332 that contact the second through-electrodes 224. The first through-electrodes 124 of the first semiconductor chip 120 may be electrically connected to the second through-electrodes 224 of the second semiconductor chip 220.

The third semiconductor chip 420 may include a fifth surface 420a and a sixth surface 420b opposing each other. The second through-electrodes 224 may vertically extend between the fifth surface 420a and the sixth surface 420b. A third circuit layer 422 of the third semiconductor chip 420 may be formed adjacent to the fifth surface 420a. The fifth surface 420a of the third semiconductor chip 420 may be an active surface, and the sixth surface 420b may be an inactive surface. The third semiconductor chip 420 may be, for example, a memory chip. The third semiconductor chip 420 may be stacked face down on the second semiconductor chip 220 so that the fifth surface 420a opposes the fourth surface 220b of the second semiconductor chip 220. The third semiconductor chip 420 may have a size similar to or equal to that of the second semiconductor chip 220.

The third semiconductor chip 420 may include second connection terminals 432 provided on the fifth surface 420a. Fifth connection pads 434 may be provided between the third circuit layer 422 and the second connection terminals 432 of the third semiconductor chip 420. A second nonconductive layer 340 may be provided on the fifth surface 420a of the third semiconductor chip 420. The second nonconductive layer 340 may be pressed so that the second connection terminals 432 contact the fourth connection pads 332. Therefore, the third semiconductor chip 420 may be electrically connected to the second semiconductor chip 220. A molding layer 250 that cover the first to third semiconductor chips 120, 220 and 420 may be formed. The molding layer 250 may expose the sixth surface 420b of the third semiconductor chip 420. In one or more exemplary embodiments of the inventive concept, the molding layer 250 may completely cover the sixth surface 420b of the third semiconductor chip 420.

The second semiconductor chip 220 may be stacked face down on the first semiconductor chip 120 so the second circuit layer 222 may oppose the first semiconductor chip 120. In one or more exemplary embodiments of the inventive concept, the second semiconductor chip 220 may be stacked face up on the first semiconductor chip 120 so the second circuit layer 222 may oppose the third semiconductor chip 420.

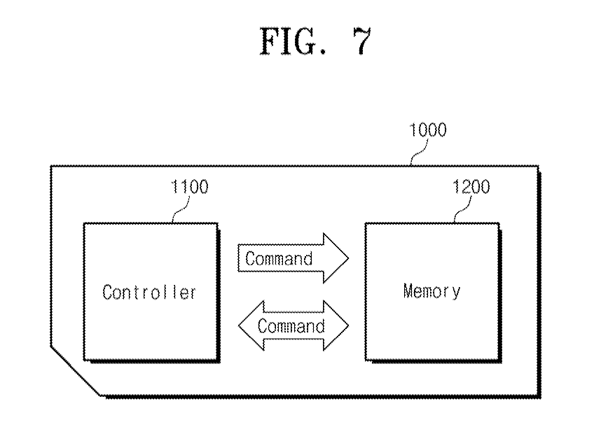

FIG. 7 is a block diagram illustrating a memory system including a semiconductor package according to one or more exemplary embodiments of the inventive concept.

Referring to FIG. 7, a controller 1100 and a memory 1200 may exchange electrical signals in a memory system 1000. For example, once the controller 1100 issues a command, the memory 1200 may transfer data. The controller 1100 and/or the memory 1200 may include a semiconductor package according to the exemplary embodiments of the inventive concept. The memory 1200 may include a memory array or a memory array bank. The memory system 1000 may include a memory card or a solid state drive (SSD).

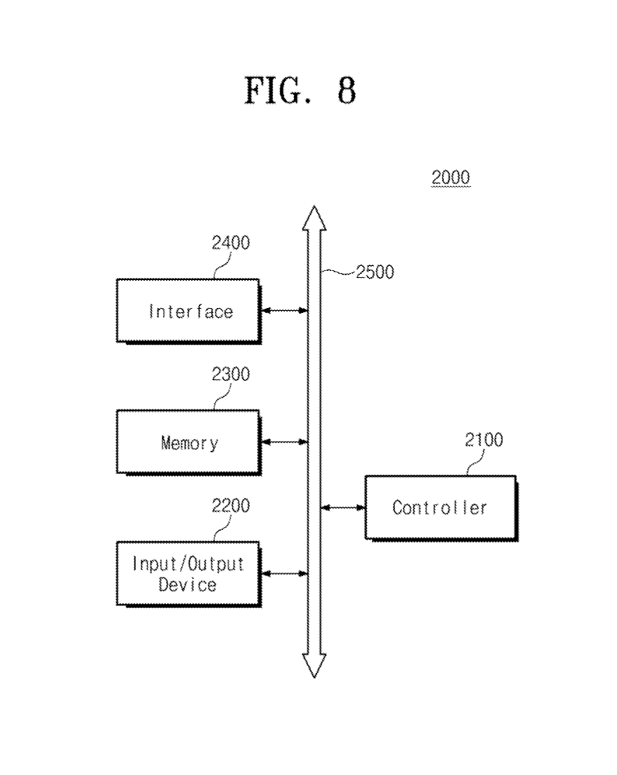

FIG. 8 is a block diagram illustrating an electronic system including a semiconductor package according to one or more exemplary embodiments of the inventive concept.

Referring to FIG. 8, an electronic system 2000 may include a controller 2100, an input/output device 2200, a memory 2300 and an interface 2400. The electronic system 2000 may be a mobile system or a system for transmitting or receiving information. The mobile system may be a personal digital assistant (PDA), a portable computer, a web tablet, a wireless phone, a mobile phone or a digital music player. The controller 2100 may serve to run programs and control the electronic system 2000. The controller 2100 may be, for example, a microprocessor, a digital signal processor, a microcontroller or the like. The input/output device 2200 may be used to input or output data of the electronic system 2000. The electronic system 2000 may be connected to an external device such as a personal computer or a network through the input/output device 2200 to exchange data with the external device. The input/output device 2200 may be, for example, a keypad, a keyboard or a display. The memory 2300 may store codes and/or data for operating the controller 2100 and/or may store data processed by the controller 2100. The controller 2100 and/or the memory 2300 may include a semiconductor package according to one or more exemplary embodiments of the inventive concept. The interface 2400 may be a data transfer path between the electronic system 2000 and another external device. The controller 2100, the input/output device 2200, the memory 2300 and the interface 2400 may communicate with each other through a bus 2500.

According to one or more exemplary embodiments of the inventive concept, a large semiconductor chip may be supported on a small semiconductor chip so that the large semiconductor chip may be prevented from being broken.

According to one or more exemplary embodiments of the inventive concept, a large semiconductor chip may be supported against a pressure applied thereto, so that the reliability of a semiconductor chip may be increased.

According to one or more exemplary embodiments of the inventive concept, semiconductor chips having different sizes may be stacked so that the yield of a semiconductor package may be increased.

The above-disclosed subject matter is to be considered illustrative and not restrictive of the spirit and scope of the inventive concept. While the present invention has been particularly shown and described with reference to exemplary embodiments thereof, it will be understood by those of ordinary skill in the art that various changes in form and detail may be made therein without departing from the spirit and scope of the present invention.

What is claimed is:

1. A method for manufacturing a semiconductor package, comprising:
providing a first semiconductor chip having a first surface and a second surface opposing each other, the first semiconductor chip comprising through-electrodes extending between the first surface and the second surface;
forming an adhesive layer on the first surface of the first semiconductor chip;
providing the first semiconductor chip on a package substrate, wherein the adhesive layer contacts the package substrate;
thermo-compressing the first semiconductor chip, wherein the adhesive layer protrudes from between the first semiconductor chip and the package substrate towards the outside of the first semiconductor chip to form a support part that covers sides of the first semiconductor chip;
providing a second semiconductor chip on the first semiconductor chip, the second semiconductor chip having a third surface and a fourth surface opposing each other, the second semiconductor chip comprising connection terminals formed on the third surface;
providing a nonconductive layer between the third surface of the second semiconductor chip and the second surface of the first semiconductor chip;
thermo-compressing the nonconductive layer, wherein the connection terminals of the second semiconductor chip are electrically connected to the through-electrodes of the first semiconductor chip; and
forming a molding layer covering at least sides of the second semiconductor chip,
wherein an upper surface of the support part is substantially flush with the second surface of the first semiconductor chip.

2. The method of claim 1, wherein the second semiconductor chip has a width that is larger than a width of the first semiconductor chip and protrudes outwardly beyond sides of the first semiconductor chip.

3. The method of claim 1, wherein the second semiconductor chip has a width that is equal to a width of the first semiconductor chip.

4. The method of claim 1, wherein the thermo-compressing the first semiconductor chip comprises thermo-compressing the first semiconductor chip using a bonding tool that has a width equal to or larger than a width of the second semiconductor chip.

5. The method of claim 1, wherein the support part is formed, wherein a sum of a width of the first semiconductor chip and an entire width of the support part is substantially equal to or larger than a width of the second semiconductor chip.

6. The method of claim 1, wherein the nonconductive layer comprises a nonconductive paste or a nonconductive film.

7. The method of claim 6, wherein the nonconductive layer has a thickness larger than a height of the connection terminals.

8. The method of claim 1, wherein the adhesive layer comprises an epoxy-based, silicon-based, phenol-type or acid anhydride hardening agent, an amine-type hardening agent or an acrylic-polymer-containing hardening material.

9. The method of claim 1, wherein the forming the molding layer comprises forming the molding layer that covers sides of the support part, covers the second semiconductor chip, and exposes the fourth surface of the second semiconductor chip.

10. The method of claim 1, further comprising:
forming a heat transfer layer on the fourth surface of the second semiconductor chip; and
forming a heat dissipating layer on the heat transfer layer.

11. A method for manufacturing a semiconductor package, comprising:
providing a first semiconductor chip having a first surface and a second surface opposing each other, the first semiconductor chip comprising first through-electrodes extending between the first surface and the second surface;
forming an adhesive layer on the first surface of the first semiconductor chip;
providing the first semiconductor chip on a package substrate, wherein the adhesive layer contacts the package substrate;
thermo-compressing the first semiconductor chip using a bonding tool wider than the first semiconductor chip, wherein the adhesive layer protrudes from between the first semiconductor chip and the package substrate towards the outside of the first semiconductor chip to form a support part that covers sides of the first semiconductor chip;
providing a second semiconductor chip on the first semiconductor chip, the second semiconductor chip having a third surface and a fourth surface opposing each other, the second semiconductor chip comprising connection terminals formed on the third surface;
providing a nonconductive layer between the third surface of the second semiconductor chip and the second surface of the first semiconductor chip; and
thermo-compressing the nonconductive layer, wherein the connection terminals of the second semiconductor chip are electrically connected to the first through-electrodes of the first semiconductor chip,
wherein the support part contacts the nonconductive layer and an upper surface of the support part is substantially flush with the second surface of the first semiconductor chip.

12. The method of claim 11, wherein the second semiconductor chip has a width that is larger than a width of the first semiconductor chip and protrudes outwardly beyond sides of the first semiconductor chip.

13. The method of claim 11, wherein the second semiconductor chip has a width that is equal to a width of the first semiconductor chip.

14. The method of claim 11, wherein the first through-electrodes are arranged in a center region of the first semiconductor chip.

15. The method of claim 11, wherein the second semiconductor chip comprises second through-electrodes connected to the connection terminals, the second through-electrodes extending between the third surface and the fourth surface, wherein the second through-electrodes of the second semiconductor chip are electrically connected to the first through-electrodes of the first semiconductor chip.

16. The method of claim 11, wherein the adhesive layer comprises an epoxy-based, silicon-based, phenol-type or acid anhydride hardening agent, an amine-type hardening agent or an acrylic-polymer-containing hardening material.

17. A method for manufacturing a semiconductor package, comprising:
providing a first semiconductor chip having a first surface and a second surface opposing each other, the first semiconductor chip comprising first through-electrodes extending between the first surface and the second surface;
forming an adhesive layer on the first surface of the first semiconductor chip;
providing the first semiconductor chip on a package substrate, wherein the adhesive layer contacts the package substrate;
thermo-compressing the first semiconductor chip using a bonding tool wider than the first semiconductor chip, wherein the adhesive layer protrudes from between the first semiconductor chip and the package substrate towards the outside of the first semiconductor chip to form a support part that covers sides of the first semiconductor chip;
providing a second semiconductor chip on the first semiconductor chip, the second semiconductor chip having a third surface and a fourth surface opposing each other, the second semiconductor chip comprising second through-electrodes that extend between the third surface and the fourth surface and connection terminals formed on the third surface;
providing a nonconductive layer between the third surface of the second semiconductor chip and the second surface of the first semiconductor chip; and
thermo-compressing the nonconductive layer, wherein the connection terminals of the second semiconductor chip are electrically connected to the first through-electrodes of the first semiconductor chip,
wherein the support part contacts the nonconductive layer and an upper surface of the support part is substantially flush with the second surface of the first semiconductor chip.

18. The method of claim 17, wherein the second semiconductor chip has a width that is larger than a width of the first semiconductor chip and protrudes outwardly beyond sides of the first semiconductor chip.

19. The method of claim 17, wherein the second semiconductor chip has a width that is equal to a width of the first semiconductor chip.

20. The method of claim 17, wherein the first through-electrodes are arranged in a center region of the first semiconductor chip.
